(19) United States
(12) Patent Application Publication
(10) Pub. No.: US 2024/0268040 A1
(43) Pub. Date: Aug. 8, 2024

(54) PROTECTIVE COVER FOR A PORTABLE ELECTRONIC DEVICE

(71) Applicant: I-Lumenate, LLC, Denver, NC (US)

(72) Inventor: William T. Rossini, Denver, NC (US)

(21) Appl. No.: 18/163,998

(22) Filed: Feb. 3, 2023

(51) Int. Cl. H05K 5/00; H01M 50/202; H05K 5/02

(52) U.S. Cl. CPC H05K 5/0086; H01M 50/202; H05K 5/023; H05K 5/0247

(57) ABSTRACT

A protective cover for a portable electronic device includes an enclosure with a front, a back, a top, a bottom, two sides, and an interior region. There is a first opening configured to receive the portable battery pack in the interior region and a receptacle disposed in the interior region adjacent to the back of the enclosure. The back of the enclosure includes a second opening to provide access to the receptacle from the exterior of the enclosure.

### TECHNICAL FIELD

The present invention relates to a protective cover for portable electronic devices, and more particularly to a flexible protective cover for a portable battery pack.

### BACKGROUND

Portable electronic devices have become ubiquitous in modern society. Many of these portable devices must be regularly recharged. Some users who spend long periods of time outdoors and away from wall outlets rely on portable battery packs, sometimes called battery banks, to recharge their electronic devices. Both portable electronic devices generally and the portable battery packs specifically are susceptible to damage from impacts when they are dropped or struck. Thus, there is a need for a protective cover to prevent impact damage to electronic devices including portable battery packs. Additionally, there is often a need to conveniently store cables, including charging cables, headphones, or other items, with the portable electronic devices/battery packs.

### SUMMARY OF THE EMBODIMENTS

The benefits and advantages of the present invention over existing systems will be readily apparent from the Summary of the Embodiments and Detailed Description to follow. One skilled in the art will appreciate that the present teachings can be practiced with embodiments other than those summarized or disclosed below.

In one aspect, the invention features a protective cover for a portable electronic device comprising an enclosure with a front, a back a top, a bottom, two sides, and an interior region. There is a first opening configured to receive the portable electronic device in the interior region and a receptacle disposed in the interior region adjacent to the back of the enclosure. The back of the enclosure includes a second opening to provide access to the receptacle from the exterior of the enclosure.

In other aspects of the invention, one or more of the following features may be included. The enclosure of the protective cover may be made of a flexible material including silicone, rubber, or plastic. The protective cover may have a third opening configured to provide access to one or both of a charging port and a discharging port on the portable electronic device when it is in the interior region. The receptacle may be configured to store a charging cable. The receptacle may further comprise a raised portion that protrudes outwardly from a portion of an exterior surface on the back of the enclosure. The receptacle may further comprise an interior receptacle wall disposed in the interior region and opposite the raised portion. The interior receptacle wall may include an interior opening enabling access to the receptacle from the interior region. The back of the enclosure may include a fourth opening, providing access to the receptacle, which is smaller than the second opening. The protective cover may further comprise textured grips on each of the two sides of the enclosure.

In further aspects of the invention, one or more of the following features may be included. The portable electronic device may be a battery pack, and the protective cover may further comprise at least one hole configured to enable visibility of at least one light on the battery pack. The protective cover may comprise a plurality of holes configured to enable visibility of a like plurality of indicator lights on the battery pack. The at least one hole may be configured to provide visibility of a flashlight on the battery pack. The protective cover may comprise a textured area, disposed on an exterior surface of the enclosure, configured to be aligned with a button on the electronic device. The enclosure may be made of one or more of leather, carbon fiber, or fabric. The top and bottom of the enclosure may be curved, and the two sides may be flat.

In another aspect, the invention features a protective cover for a portable battery pack comprising: a flexible enclosure with a front, a back, a top, a bottom, two sides, and an interior region; a first opening configured to receive the battery pack; textured grips on the two sides of the flexible enclosure; and a receptacle disposed in the interior region adjacent to the back of the flexible enclosure, wherein the receptacle is defined by an interior receptacle wall disposed in the interior region and a raised portion that protrudes outwardly from a portion of an exterior surface of the back of the flexible enclosure, and wherein the raised portion includes an opening to provide access to the receptacle from the exterior of the flexible enclosure.

These and other features of the invention will be apparent from the following detailed description and the accompanying figures.

### BRIEF DESCRIPTION OF THE DRAWINGS

The foregoing features of embodiments will be more readily understood by reference to the following detailed description, taken with reference to the accompanying drawings, in which:

FIG. 1 depicts a front side view of an embodiment of the protective cover according to an aspect of this disclosure;

FIG. 2 depicts a back side view of the protective cover according to the embodiment of FIG. 1;

FIG. 3 depicts a top view of the protective cover according to the embodiment of the previous figures;

FIG. 4 depicts a bottom view of the protective cover according to the embodiment of the previous figures;

FIG. 5A depicts a left side view of the protective cover according to the embodiment of the previous figures, including a textured grip;

FIG. 5B depicts a right side view of the protective cover according to the embodiment of the previous figures, including a textured grip;

FIG. 6 depicts a perspective view of the front, top, and left sides of the protective cover according to the embodiment of the previous figures.

FIG. 7 depicts a perspective view of the back, bottom, and right sides of the protective cover according to the embodiment of the previous figures;

FIG. 8 depicts a cross-sectional view of the protective cover according to the embodiment of the previous figures;

FIG. 9 depicts a perspective view of the front, top, and left sides of the protective cover according to the embodiment of the previous figures when a portable battery pack is inside of it.

FIG. 10 depicts a perspective view of the back, bottom, and right sides of the protective cover according to the embodiment of the previous figures when a portable battery pack is inside of it.

FIG. 11 depicts a left side view of the protective cover according to the embodiment of the previous figures when a portable battery pack is inside of it.

### DETAILED DESCRIPTION OF SPECIFIC EMBODIMENTS

The disclosure and the various features and advantageous details thereof are explained more fully with reference to the non-limiting embodiments and examples that are described and/or illustrated in the accompanying drawings and detailed in the following description. It should be noted that the features illustrated in the drawings are not necessarily drawn to scale, and features of one embodiment may be employed with other embodiments as the skilled artisan would recognize, even if not explicitly stated herein.

Descriptions of well-known components and processing techniques may be omitted so as to not unnecessarily obscure the embodiments of the disclosure. The examples used herein are intended merely to facilitate an understanding of ways in which the disclosure may be practiced and to further enable those of skill in the art to practice the embodiments of the disclosure. Accordingly, the examples and embodiments herein should not be construed as limiting the scope of the disclosure. Moreover, it is noted that like reference numerals represent similar parts throughout the several views of the drawings.

Definitions. As used in this description and the accompanying claims, the following terms shall have the meanings indicated, unless the context otherwise requires:

“Portable electronic device” includes, for example, cell phones including smart phones, battery banks, cameras, GPS devices, music players, portable hard drives, portable video game systems, portable speakers, etc.

While we depict the protective cover herein encasing a portable battery pack this is only an exemplary embodiment and it is not intended to be limiting. The protective cover disclosed and claimed herein may be readily used to enclose various types of portable electronic devices with various form factors and those skilled in the art will appreciate that the concepts and configurations disclosed herein will be readily adaptable to other electronic device types.

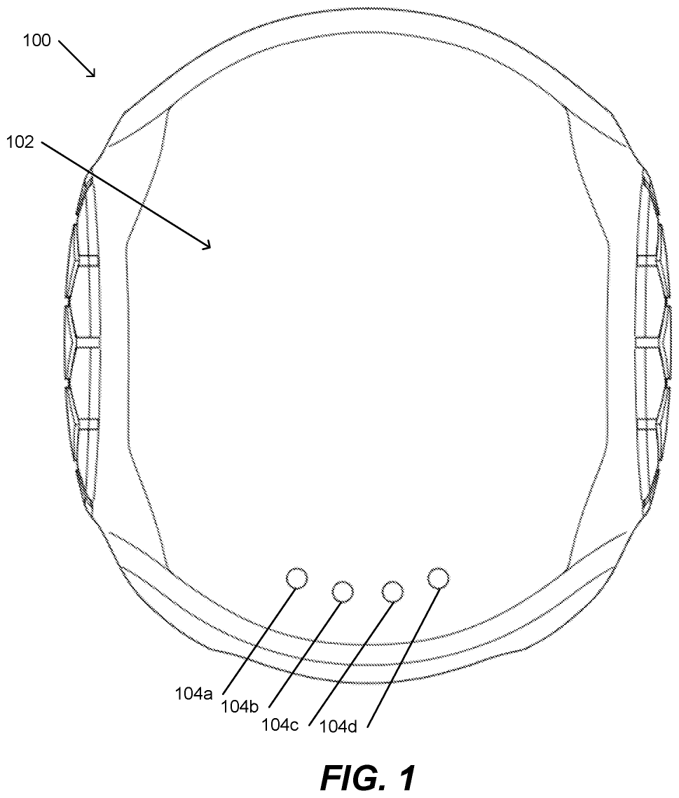

FIG. 1 depicts a frontal view of an embodiment of a protective cover 100 according to this disclosure for use with an exemplary portable battery pack. The protective cover 100 may be formed of a variety of materials, but is preferably made of a flexible material such as silicone. Protective cover 100 has a front side 102, which may be called a front side, front face, or front portion interchangeably herein. On the front side 102, there may be one or more holes configured to provide visibility to one or more indicator lights on a portable electronic device when the portable electronic device is disposed inside the protective cover 100. In this embodiment, four holes 104a, 104b, 104c, and 104d are depicted to provide visibility to four, corresponding, indicator lights on a portable battery pack. Such indicator lights may, for example, illuminate in such a way as to indicate the level of remaining charge in the portable battery pack. Although FIG. 1 depicts holes on the front side 102, the holes, when present, may be located on any one or more other surfaces of the protective cover. There may be fewer or more holes, depending on the number of indicator lights on the portable electronic device.

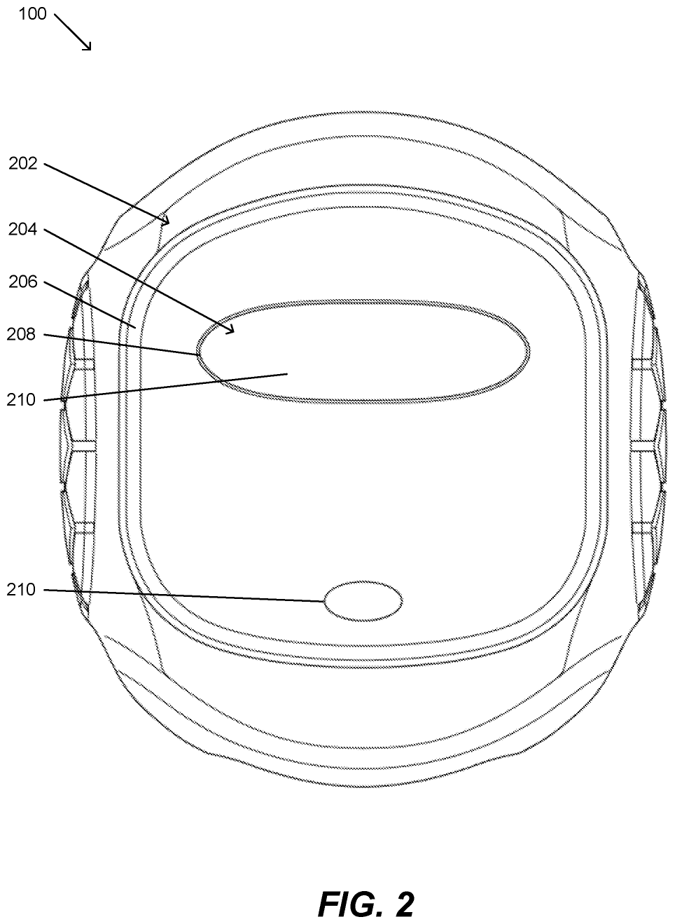

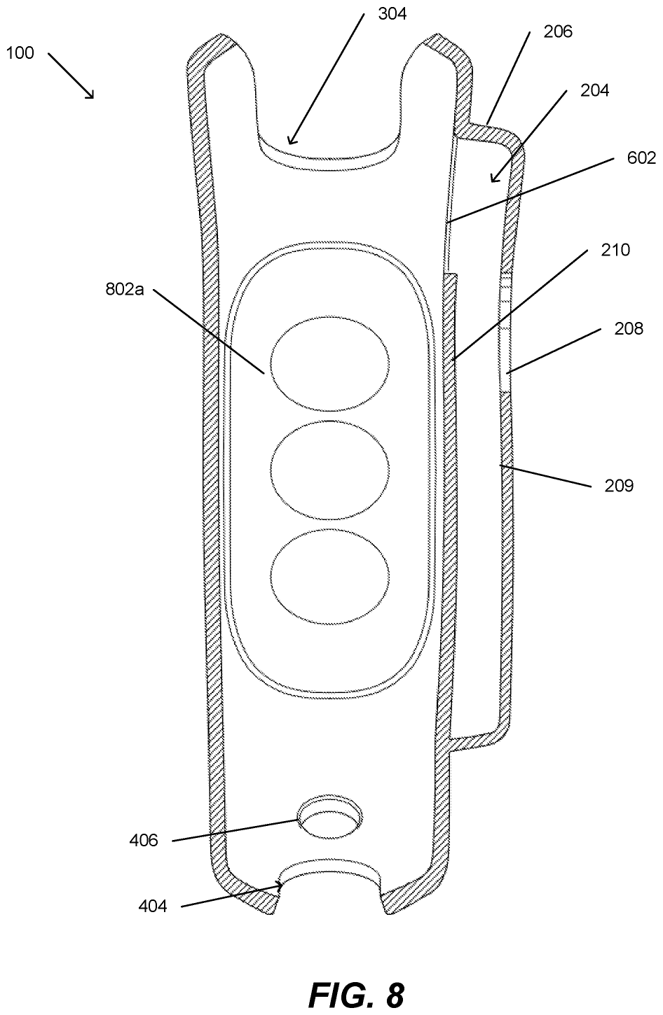

FIG. 2 depicts a rear side view of protective cover 100 having a back side 202, which may be called a back side, back portion, or back face. FIG. 2 also partially depicts a receptacle 204, formed in the interior region of protective cover 100, and depicted and described more fully below. Receptacle 204 is formed in part by a raised portion 206 that protrudes outwardly from a portion of the back side 202 of protective cover 100, and an interior receptacle wall 210 that is opposite the raised portion 206 and configured to separate the receptacle 204 from a portable electronic device. The interior receptacle wall 210 is also seen clearly in the cross-sectional view of FIG. 8. The raised portion 206 further comprises an interior surface 209, which is shown in FIG. 8.

As depicted in this embodiment, there is a second opening 208 in the surface of raised portion 206, which is configured to provide access to the receptacle 204 from the exterior of protective cover 100. In addition, there may be a fourth opening 212, which may be smaller than the second opening 208, and configured to provide access to the receptacle 204. The receptacle 204 may be configured to store charging cables compatible with a portable electronic device. It may also be configured to store other objects, such as wall outlet adapters, credit cards, cash, coins, memory cards, headphones or earbuds, or electronic devices.

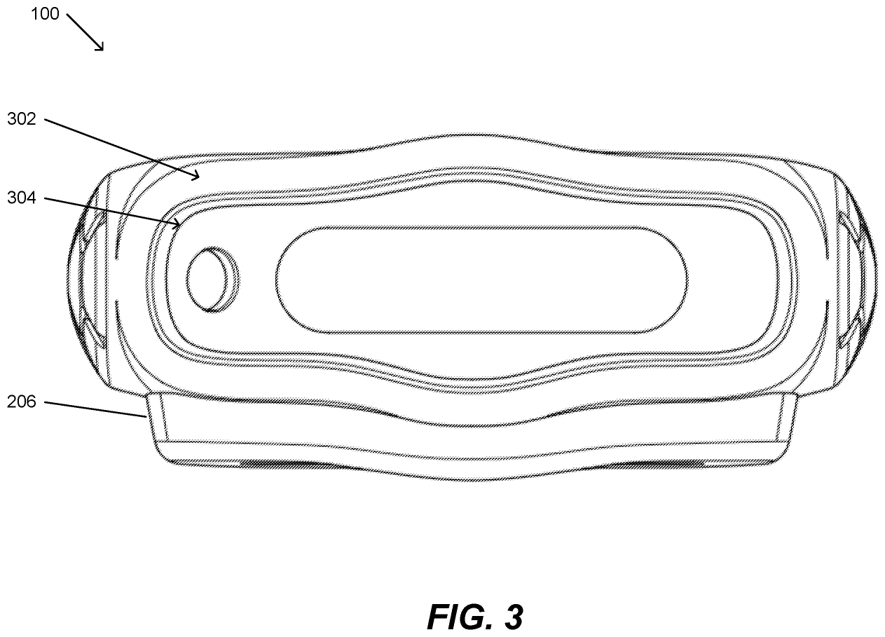

FIG. 3 depicts a top view of protective cover 100 having a top side 302, which may be called a top side, top face, or top portion, and which may further comprise a first opening 304, configured to receive a portable electronic device in the interior region of protective cover 100. The top side 302 may have a curved surface, which may be better seen, for example, in FIG. 1 or FIG. 2. The surface of top side 302 may be a different shape, depending on the shape of the top side of the portable electronic device. The first opening 304 may be configured to enable visibility of the top side of the portable electronic device for viewing a compass, which may typically be included on a portable battery pack, when the portable battery pack is in the interior region. FIG. 3 also depicts a top view of raised portion 206, which partially defines receptacle 204, as described above.

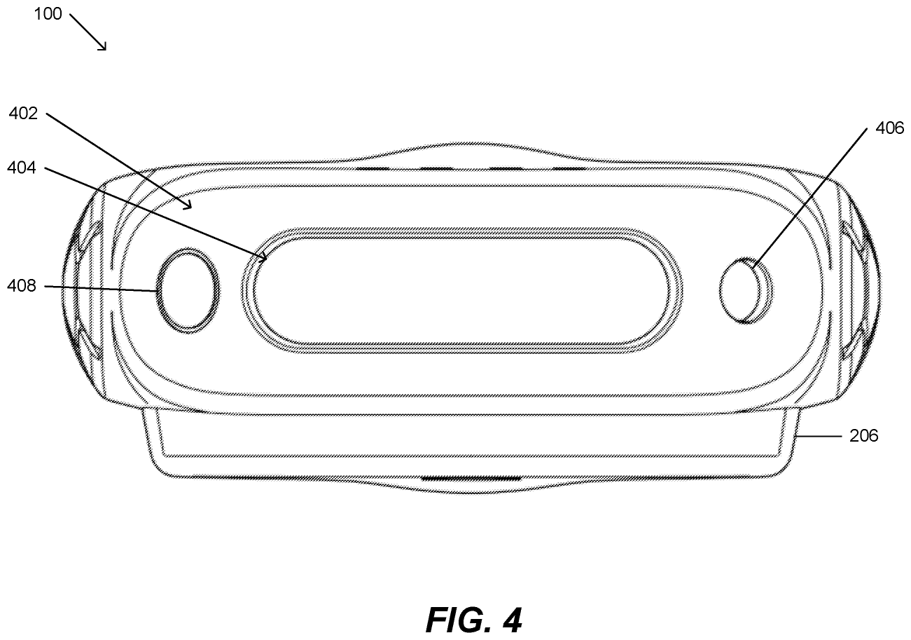

FIG. 4 depicts a bottom view of protective cover 100 having a bottom side 402, which may be called a bottom side, bottom face, or bottom portion. The bottom side 402 comprises a third opening 404, which may be configured to provide access to one or both of a charging port and a discharging port on a portable electronic device, such as a portable battery pack, when the portable electronic device is in the interior region of the protective cover 100. The surface of the bottom side 402 may be curved, just as the top surface is curved. This may be better seen, for example, in FIG. 1 or FIG. 2. The surface of the bottom side 402 may be a different shape, depending on the shape of the bottom side of the portable electronic device. The bottom side 402 may further comprise a hole 406 configured to enable visibility of a flashlight on a portable electronic device. The hole 406, if present, may instead be located on any other face of the protective cover, to correspond with the location of the flashlight.

The bottom side 402 may further comprise a textured area 408, disposed on the exterior surface of the protective cover 100, configured to be aligned with a button on a portable electronic device. The textured area 408 may instead be located on any other face of the protective cover 100 depending on the location and presence of the button on the portable electronic device. FIG. 4 also depicts a bottom view of raised portion 206, which partially defines receptacle 204, as described above.

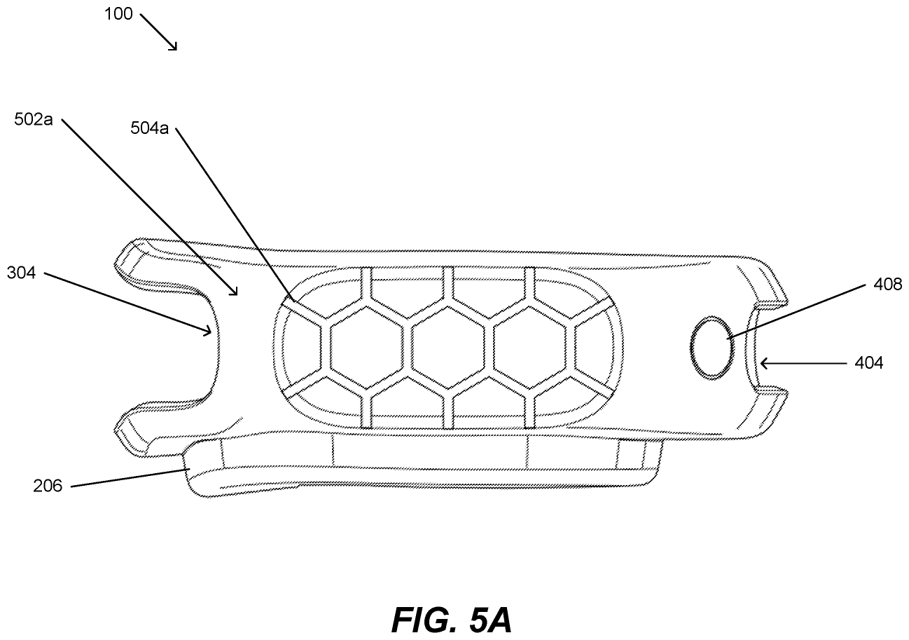

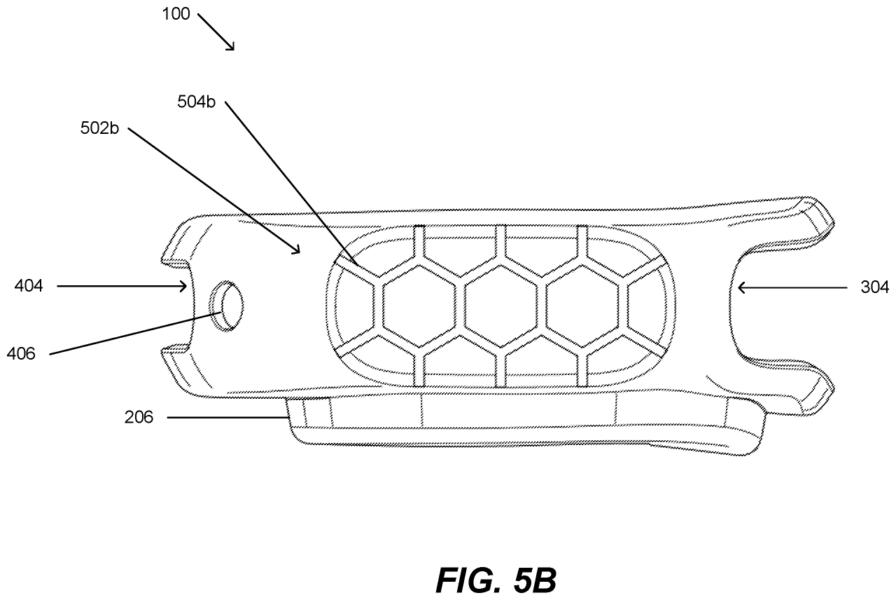

FIG. 5A depicts a side view of protective cover 100. The protective cover 100 comprises a left side 502a, which may be called a left side, left face, or left portion. The left side 502a may comprise a textured grip area 504a, configured to make holding, by a user, a portable electronic device in the protective cover easier and more comfortable. The left side 502a may be substantially straight, as seen in FIG. 1 and FIG. 2, and parallel with right side 502b described below with respect to FIG. 5B. The left side 502a may be shaped differently, depending on the shape of the portable electronic device. FIG. 5A also depicts a side view of raised portion 206, which partially defines receptacle 204. FIG. 5A additionally depicts the textured area 408, the first opening 304 and the third opening 404.

FIG. 5B depicts another side view of protective cover 100, a right side 502b, which may be called a right side, right face, or right portion, and which may be opposite left side 502a. The right side 502b may comprise a textured grip 504b, configured to make holding, by a user, a portable electronic device in the protective cover easier and more comfortable. The right side 502b may be substantially straight, as seen in FIG. 1 and FIG. 2, and parallel with left side 502a. The right side 502b may be shaped differently, depending on the shape of the portable electronic device. FIG. 5B also depicts a side view of raised portion 206, which partially defines receptacle 204, and the hole 406, the first opening 304, as well as the third opening 404.

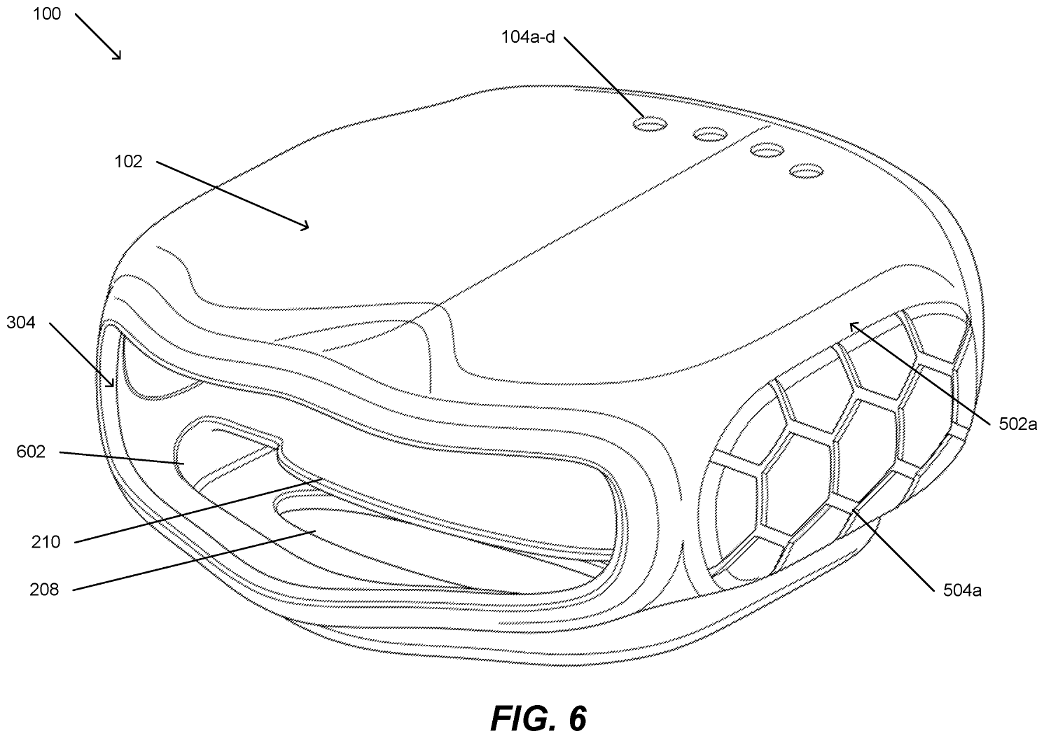

FIG. 6 depicts a perspective view of the front side, left side, and top side of protective cover 100. FIG. 6 depicts, inter alia, the front side 102 on which where may be a plurality of holes 104a-d. This view also depicts the left side 502a, on which there may be the textured grip 504a and the first opening 304, the interior receptacle wall 210, which partially defines receptacle 204 (not labelled in this figure), the second opening 208, and an interior aperture 602, which is configured to provide access to the receptacle 204 from the interior region of protective cover 100.

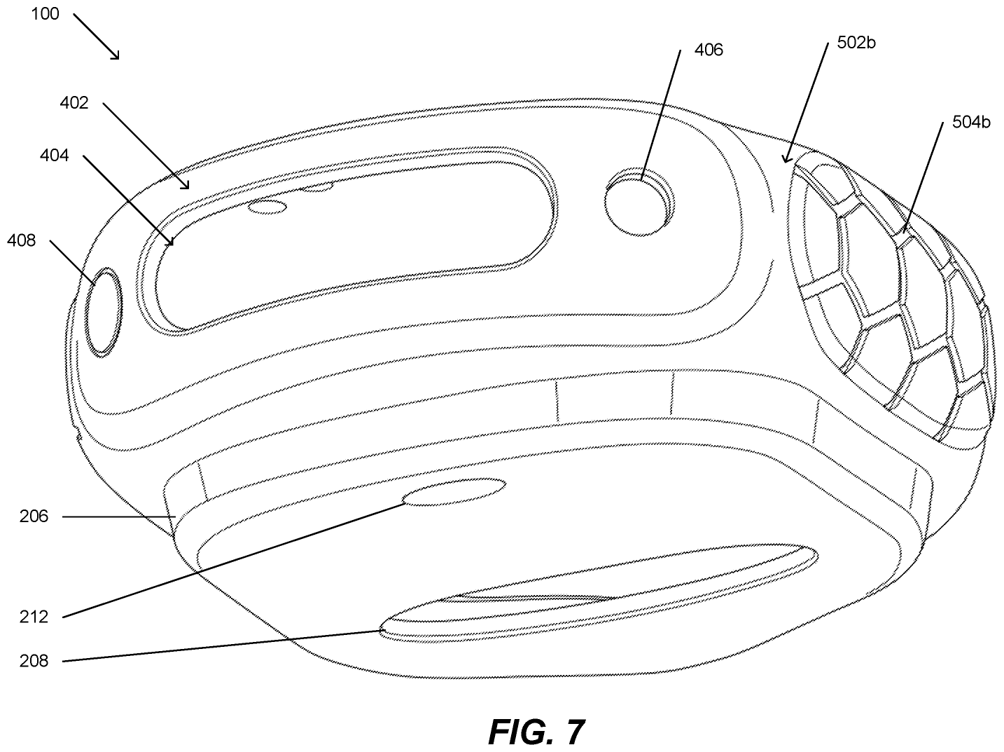

FIG. 7 depicts a perspective view of the back side, bottom side, and right side of protective cover 100. FIG. 7 depicts, inter alia, the bottom side 402, on which there is the third opening 404, the hole 406, and the textured area 408. FIG. 7 also depicts the right side 502b, on which there is the textured grip 504b. FIG. 7 also depicts a perspective view of raised portion 206, which partially defines receptacle 204, on which there is the second opening 208 and the fourth opening 212.

FIG. 8 depicts a cross-sectional view of protective cover 100 including the first opening 304, the third opening 404, and the hole 406. FIG. 8 also depicts a cross-sectional view of raised portion 206, which has the interior surface 209 which together with interior receptacle wall 210, define receptacle 204. Receptacle 204 also comprises second opening 208. FIG. 8 also depicts interior aperture 602, which is configured to provide access to the receptacle 204 from the interior region of protective cover 100. The receptacle 204 may be configured to store charging cables compatible with a portable electronic device. It may also be configured to store other objects, such as wall outlet adapters, credit cards, cash, coins, memory cards, headphones or earbuds, or electronic devices.

FIG. 8 also depicts an interior grip mold 802a, which is an optional feature disposed on the opposite surface of left side 502a as textured grip 504a, and which is configured to conform to a textured side of the portable electronic device. There may also be an interior grip mold 802b (not shown) disposed on the opposite surface of right side 502b as textured grip 504b.

The protective cover as described above may be composed of one or more of silicone, rubber, plastic, leather, carbon fiber, fabric, or similar materials. Further, it is also contemplated that the protective cover may or may not be flexible. For example, protective cover may be made of silicone and may be configured temporarily deform in order to receive the portable electronic device. In another example, the enclosure may be composed of two or more rigid pieces that operate to connect together around the body of a portable electronic device in order to create a protective case. The portable electronic device may be a portable battery pack.

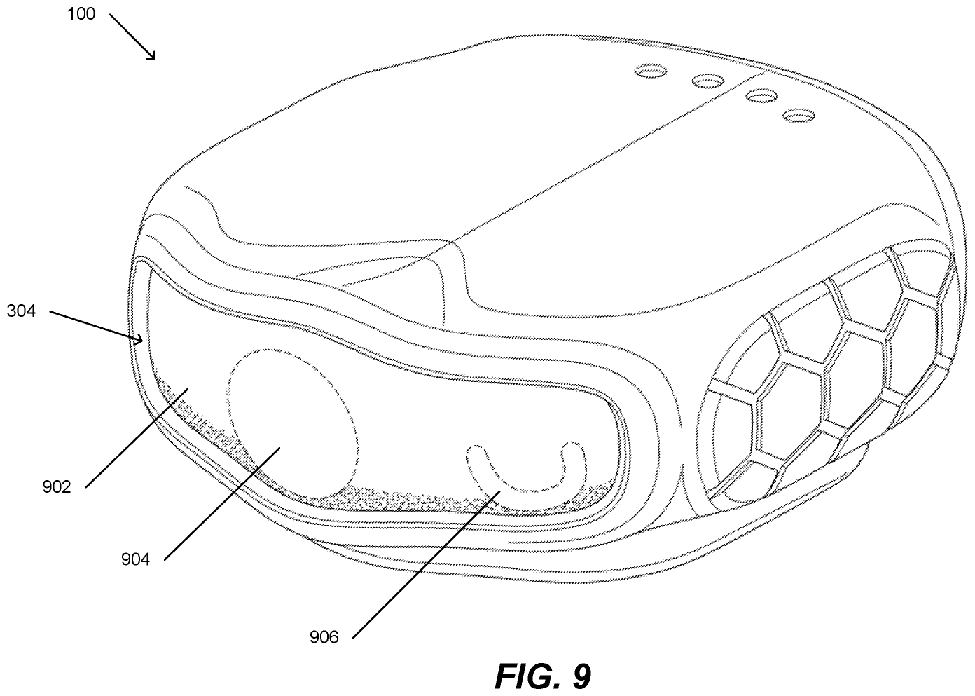

FIG. 9 depicts a perspective view of the front, top, and left sides of the protective cover 100 when a portable battery pack 902 is inside of it. Inter alia, the portable battery pack 902 can be seen disposed in the interior of the protective cover 100 through the first opening 304. The portable battery pack 902 may comprise a compass 904 (which outline is shown in FIG. 9) and a hoop 906, which may enable attachment of, for example, a wrist strap or carabiner.

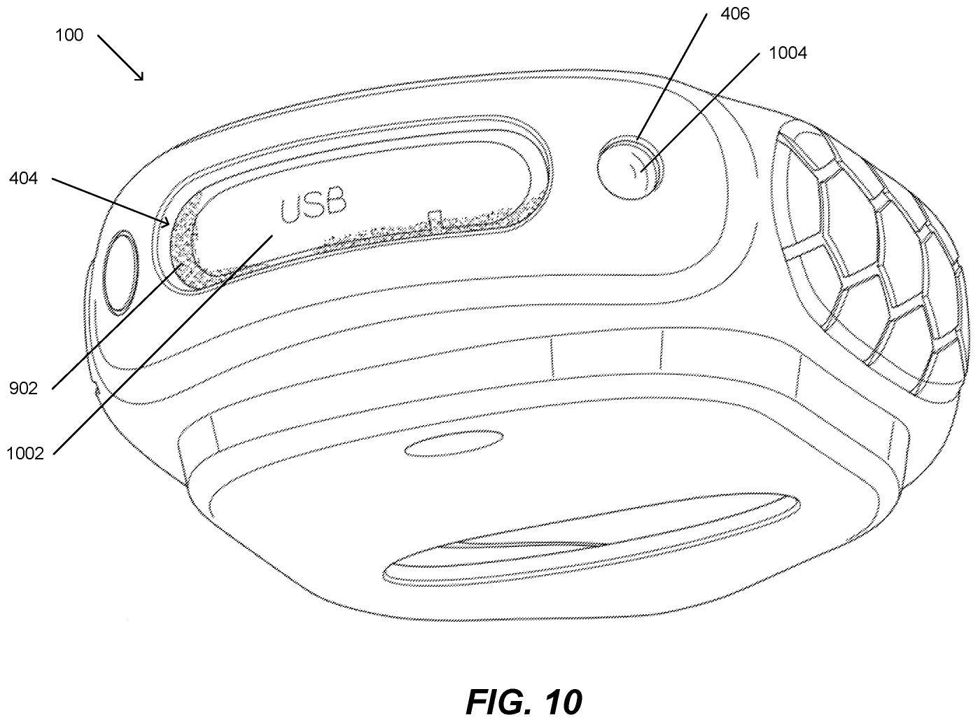

FIG. 10 depicts a perspective view of the back, bottom, and right sides of the protective cover 100 when the portable battery pack 902 is inside of it. Inter alia, the portable battery pack 902 can be seen disposed in the interior of the protective cover 100 through the third opening 404. The portable battery pack 902 may comprise a USB flap 1002 configured to protect the charging and discharging ports on the portable battery pack 902 and which may make the portable battery pack 902 waterproof when closed. The portable battery pack 902 may also comprise a flashlight 1004, which may be seen through the hole 406.

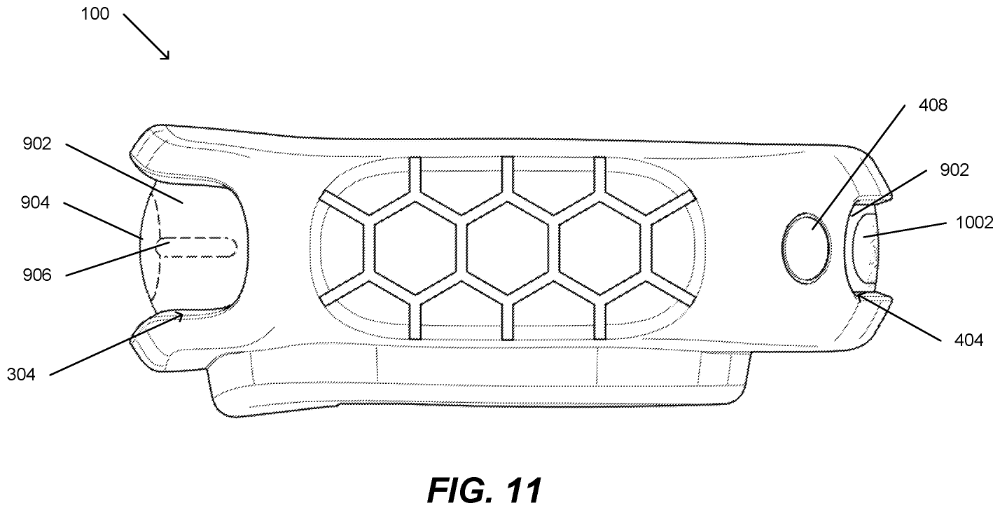

FIG. 11 depicts a left side view of the protective cover 100 when the portable battery pack 902 is inside of it. Inter alia, the portable battery pack 902 can be seen disposed in the interior of the protective cover 100 through the first opening 304 and the third opening 404. The portable battery pack 902 may comprise the compass 904, the hoop 906, and the USB flap 1002. The protective cover 100 may also comprise the textured area 408 disposed to be covering a button (not shown) on the portable battery pack 902.

The embodiments of the invention described above are intended to be merely exemplary; numerous variations and modifications will be apparent to those skilled in the art. All such variations and modifications are intended to be within the scope of the present invention as defined in any appended claims.

What is claimed is:

1. A protective cover for a portable electronic device comprising:
an enclosure with a front, a back, a top, a bottom, two sides, and an interior region;
a first opening configured to receive the portable electronic device in the interior region; and
a receptacle disposed in the interior region adjacent to the back of the enclosure;
wherein the back of the enclosure includes a second opening to provide access to the receptacle from the exterior of the enclosure.

2. The protective cover of claim 1, wherein the enclosure is made of a flexible material including silicone, rubber, or plastic.

3. The protective cover of claim 1, further comprising a third opening configured to provide access to one or both of a charging port and a discharging port on the portable electronic device when in the interior region.

4. The protective cover of claim 1 wherein the receptacle is configured to store a charging cable.

5. The protective cover of claim 1 wherein the receptacle further comprises a raised portion that protrudes outwardly from a portion of an exterior surface of the back of the enclosure.

6. The protective cover of claim 5 wherein the receptacle further comprises an interior receptacle wall disposed in the interior region and opposite the raised portion.

7. The protective cover of claim 6, wherein the interior receptacle wall includes an interior opening enabling access to the receptacle from the interior region.

8. The protective cover of claim 7 wherein the back of the enclosure includes a fourth opening, providing access to the receptacle, which is smaller than the second opening.

9. The protective cover of claim 1 further comprising textured grips on each of the two sides of the enclosure.

10. The protective cover of claim 1, wherein the portable electronic device is a battery pack, further comprising at least one hole configured to enable visibility of at least one light on the battery pack.

11. The protective cover of claim 10 further comprising a plurality of holes configured to enable visibility of a like plurality of indicator lights on the battery pack.

12. The protective cover of claim 10 wherein the at least one hole is configured to enable visibility of a flashlight on the battery pack.

13. The protective cover of claim 1 further comprising a textured area, disposed on an exterior surface of the enclosure, configured to be aligned with a button on the electronic device.

14. The protective cover of claim 1 wherein the enclosure is made of one or more of leather, carbon fiber, or fabric.

15. The protective cover of claim 1 wherein the top and bottom of the enclosure are curved and the two sides are flat.

16. A protective cover for a portable battery pack comprising:
a flexible enclosure with a front, a back, a top, a bottom, two sides, and an interior region;
a first opening configured to receive the battery pack;
textured grips on the two sides of the flexible enclosure; and
a receptacle disposed in the interior region adjacent to the back of the flexible enclosure, wherein the receptacle is defined by an interior receptacle wall disposed in the interior region and a raised portion that protrudes outwardly from a portion of an exterior surface of the back of the flexible enclosure, and wherein the raised portion includes an opening to provide access to the receptacle from the exterior of the flexible enclosure.
